(19) United States
(12) Patent Application Publication
(10) Pub. No.: US 2025/0124998 A1
(43) Pub. Date: Apr. 17, 2025

(54) SEMICONDUCTOR DEVICE FOR CONTROLLING OPERATING POWER SUPPLIED TO WORD LINE DRIVER

(71) Applicant: SK hynix Inc., Icheon-si Gyeonggi-do (KR)

(72) Inventor: Byeong Cheol LEE, Icheon-si Gyeonggi-do (KR)

(73) Assignee: SK hynix Inc., Icheon-si Gyeonggi-do (KR)

(21) Appl. No.: 18/442,833

(22) Filed: Feb. 15, 2024

(30) Foreign Application Priority Data
Oct. 13, 2023 (KR) 10-2023-0137165

(51) Int. Cl. G11C 29/46; G11C 29/12

(52) U.S. Cl. CPC G11C 29/46; G11C 29/12005; G11C 2029/1202

(57) ABSTRACT

A semiconductor device may include a power control signal generation circuit configured to generate a power control signal that is activated when at least one of a power-up period and a test mode operation are performed and an operating power generation circuit configured to set operating power supplied to a word line driver as a high voltage in response to the power control signal.

### CROSS-REFERENCE TO RELATED APPLICATION

The present application claims priority under 35 U.S.C. § 119(a) to Korean Patent Application No. 10-2023-0137165, filed in the Korean Intellectual Property Office on Oct. 13, 2023, the entire disclosure of which is incorporated herein by reference.

### BACKGROUND

The present disclosure relates to a semiconductor device for controlling operating power supplied to a word line driver.

In general, a semiconductor device, such as DRAM, performs an operation of accessing a memory cell, in order to perform a write operation of storing data in the memory cell and a read operation of outputting the data that have been stored in the memory cell. The active operation may be performed in a way to select one of main word line signals responsive to a row address, enable the selected main word line signal, select at least one of word line signals that have been allocated to the selected main word line signal, and enable the selected at least one, word line signal.

### SUMMARY

In an embodiment, a semiconductor device may include a power control signal generation circuit configured to generate a power control signal that is activated when at least one of: a power-up period is started, a test mode operation is performed, and an operating power generation circuit is configured to set operating power supplied to a word line driver as a high voltage in response to the power control signal.

In an embodiment, a semiconductor device may include: a latch signal generation circuit configured to generate a latch signal responsive to a power-up signal and a feedback voltage; a first voltage setting circuit configured to generate a first voltage responsive to the latch signal and a test mode signal; a second voltage setting circuit configured to generate a second voltage responsive to a mat selection signal and configured to generate the feedback voltage responsive to the second voltage; and a control signal output circuit configured to generate a power control signal for setting a voltage level of operating power that is supplied to a word line driver responsive to the first voltage and the second voltage.

### BRIEF DESCRIPTION OF THE DRAWINGS

FIG. 1 is a block diagram illustrating a construction of a semiconductor device according to an embodiment of the present disclosure.

FIG. 2 is a circuit diagram according to an example of a power control signal generation circuit that is included in the semiconductor device illustrated in FIG. 1.

FIG. 3 is a circuit diagram according to an example of an operating power generation circuit that is included in the semiconductor device illustrated in FIG. 1.

FIG. 4 is a block diagram according to an example of a word line driver that is included in the semiconductor device illustrated in FIG. 1.

FIG. 5 is a circuit diagram according to an example of a main word line driver that is included in the word line driver illustrated in FIG. 4.

FIG. 6 is a circuit diagram according to an example of a sub-word line driver that is included in the word line driver illustrated in FIG. 4.

FIGS. 7 and 8 are timing diagrams for describing an operation of a power control signal that controls the generation of operating power in the semiconductor device illustrated in FIG. 1.

FIG. 9 is a block diagram illustrating a construction of a semiconductor system according to an embodiment of the present disclosure.

FIG. 10 is a block diagram illustrating a construction of an electronic system according to an embodiment of the present disclosure.

FIG. 11 is a block diagram illustrating a construction of an electronic system according to another embodiment of the present disclosure.

### DETAILED DESCRIPTION

In the descriptions of the following embodiments, the term “preset” indicates that the numerical value of a parameter is previously decided, when the parameter is used in a process or algorithm. According to an embodiment, the numerical value of the parameter may be set when the process or algorithm is started or while the process or algorithm is performed.

Terms such as “first” and “second,” are used to distinguish the identify of components, and are not to be construed as limiting components. For example, a “first” component may be referred to as a “second” component for identification purposes, and vice versa.

When one component is referred to as being “coupled” or “connected” to another component, it should be understood that the components may be directly coupled or connected to each other or coupled or connected to each other through another component interposed therebetween. In contrast, when one component is referred to as being “directly coupled” or “directly connected” to another component, it should be understood that the components are directly coupled or connected to each other without another component interposed therebetween.

A “logic high level” and a “logic low level” are used to describe the logic levels of signals. A signal having a “logic high level” is distinguished from a signal having a “logic low level.” For example, when a signal having a first voltage corresponds to a signal having a “logic high level,” a signal having a second voltage may correspond to a signal having a “logic low level.” According to an embodiment, a “logic high level” may be set to a voltage higher than a “logic low level.” According to an embodiment, the logic levels of signals may be set to different logic levels or opposite logic levels. For example, a signal having a logic high level may be set to have a logic low level in some embodiments, and a signal having a logic low level may be set to have a logic high level in some embodiments.

A “logic bit set” may mean a combination of logic levels of bits included in a signal. When a logic level of each of the bits included in the signal is changed, a logic bit set of the signal may be differently set. For example, if two bits are included in a signal, a logic bit set of the signal may be set as a first logic bit set when logic levels of the two bits included in the signal are a “logic low level” and a “logic low level”, and may be set as a second logic bit set when logic levels of the two bits included in the signal are a “logic low level”, and a “logic high level.”

Hereafter, the present disclosure will be described in more detail through embodiments. The embodiments are only used to exemplify the present disclosure, and the scope of the present disclosure is not limited by the embodiments.

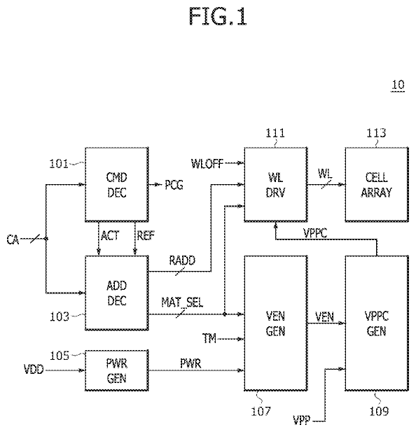

FIG. 1 is a block diagram illustrating a configuration of a semiconductor device 10 according to an embodiment of the present disclosure. As illustrated in FIG. 1, the semiconductor device 10 may include a command decoder (CMD DEC) 101, an address decoder (ADD DEC) 103, a power-up signal generation circuit (PWR GEN) 105, a power control signal generation circuit (VEN GEN) 107, an operating power generation circuit (VPPC GEN) 109, a word line driver (WL DRV) 111, and a cell array (CELL ARRAY) 113.

The command decoder 101 may generate an active signal ACT, a refresh signal REF, and a precharge signal PCG, responsive to a command address CA. The command decoder 101 may generate the active signal ACT, the refresh signal REF, and the precharge signal PCG by extracting a command from the command address CA and decoding the command extracted from the command address CA. The command decoder 101 may generate the active signal ACT that is activated in an active operation for accessing at least one of memory cells of the cell array 113. The command decoder 101 may generate the refresh signal REF that is activated for a refresh operation for the memory cells of the cell array 113. The command decoder 101 may generate the precharge signal PCG that is activated for a precharge operation for the cell array 113. The command decoder 101 may be electrically connected to the address decoder 103, and may supply the active signal ACT and the refresh signal REF to the address decoder 103.

The address decoder 103 may generate a mat selection signal MAT_SEL and a row address RADD, responsive to the command address CA, the active signal ACT, and the refresh signal REF. The address decoder 103 may generate the mat selection signal MAT_SEL and the row address RADD by extracting an address from the command address CA when the active operation or the refresh operation is performed and decoding the address that has been extracted from the command address CA. When the cell array 113 may be divided into a plurality of mats (not illustrated) and may be controlled in the mat units, the mat selection signal MAT_SEL may include bits the logic bit set of which is set in order to select at least one of the mats of the cell array 113. When the memory cells of the cell array 113 are connected to a plurality of word lines WL, the row address RADD may include bits which may be “set” to a logic one or logic zero, in order to select at least one of the word lines connected to the memory cells in the cell array 113. The address decoder 103 may be electrically connected to the power control signal generation circuit 107 and the word line driver 111 and may supply the mat selection signal MAT_SEL to the power control signal generation circuit (VEN GEN) 107 and supply the mat selection signal MAT_SEL and the row address RADD to the word line driver 111.

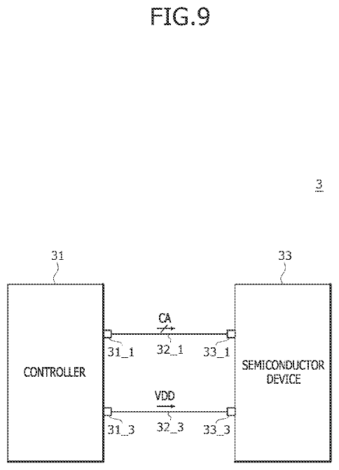

The power-up signal generation circuit 105 may generate a power-up signal PWR responsive to a power source voltage VDD. The power-up signal generation circuit 105 may generate the power-up signal PWR having a first logic level during a power-up period, during which the power source voltage VDD supplied from a controller (e.g., 31 in FIG. 9) to the semiconductor device 10, rises or increases from a low level, typically at or near 0 V to a target voltage level, (which will be semiconductor-device dependent and may thus may vary from one semiconductor technology to another) and may then generate the power-up signal PWR having a second logic level after completion of the power-up period. In an alternate embodiment, the first logic level may be set as a logic high level and the second logic level may be set as a logic low level. The power-up signal generation circuit 105 may be electrically connected to the power control signal generation circuit 107, and may supply the power-up signal PWR to the power control signal generation circuit 107.

The power control signal generation circuit 107 may generate a power control signal VEN, responsive to the mat selection signal MAT_SEL, the power-up signal PWR, and a test mode signal TM. The power control signal generation circuit 107 may generate the power control signal VEN when the power-up signal PWR is activated in the power-up period. That is, the power control signal generation circuit 107 may generate the activated power control signal VEN when the power-up period is started. The power control signal generation circuit 107 may generate the power control signal VEN when the test mode signal TM is activated in a test mode. The power control signal generation circuit 107 may generate the power control signal VEN when the precharge operation is performed, after at least one of mats (not illustrated) of the cell array 113 is selected by the mat selection signal MAT_SEL and at least one of the active operation and the a refresh operation are performed. The mat selection signal MAT_SEL may include bits corresponding to the selected mats (not illustrated), respectively, which are included in the cell array 113. For example, if the cell array 113 may include a first mat and a second mat, a first bit MAT_SEL<1> of the mat selection signal MAT_SEL may indicate the first mat, and a second bit MAT_SEL<2> of the mat selection signal MAT_SEL may indicate the second mat. The power control signal generation circuit 107 may be electrically connected to the operating power generation circuit 109, and may supply the power control signal VEN to the operating power generation circuit 109.

The operating power generation circuit 109 may generate an operating power VPPC from a high voltage VPP responsive to the power control signal VEN. When the power control signal VEN is activated, the operating power generation circuit 109 may set the operating power VPPC as the high voltage VPP. For example, the high voltage VPP may be a pumping voltage greater than the power voltage VDD. When the power control signal VEN is deactivated, the operating power generation circuit 109 may maintain the voltage level of the operating power VPPC so that the voltage level of the operating power VPPC does not drop to a voltage level or less, which is obtained by subtracting a preset voltage level from the voltage level of the high voltage VPP. Although the power control signal VEN is deactivated, the operating power generation circuit 109 may prevent sudden drops in the operating power VPPC.

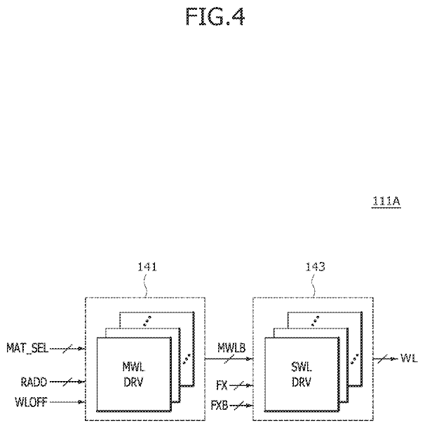

The word line driver 111 may drive the word line WL responsive to the mat selection signal MAT_SEL, the row address RADD, and a word line off signal WLOFF. The word line off signal WLOFF may be activated when the active operation or the refresh operation is not performed. The word line driver 111 may drive a selected main word line (e.g., MWLB in FIG. 4) by the operating power VPPC responsive to the mat selection signal MAT_SEL and the row address RADD in the state in which the word line off signal WLOFF has been deactivated. The word line driver 111 may drive the word line WL responsive to the main word line MWLB that is driven by the operating power VPPC.

The cell array 113 may include a plurality of mats (not illustrated) that are selected by the mat selection signal MAT_SEL. Each of the mats of the cell array 113 may include a plurality of memory cells that are connected to the word line WL. When the active operation or the refresh operation is performed, the memory cells of the cell array 113 and that are connected to the word line WL that is selected and driven by the mat selection signal MAT_SEL and the row address RADD may be accessed.

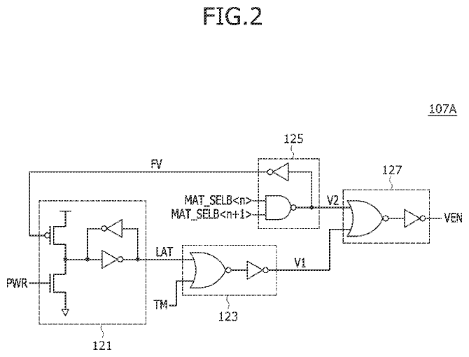

FIG. 2 is a circuit diagram of a power control signal generation circuit 107A according to an example of the power control signal generation circuit 107 of FIG. 1. As illustrated in FIG. 2, the power control signal generation circuit 107A may include a latch signal generation circuit 121, a first voltage setting circuit 123, a second voltage setting circuit 125, and a control signal output circuit 127.

The latch signal generation circuit 121 may generate a latch signal LAT responsive to the power-up signal PWR and a feedback voltage FV. The latch signal generation circuit 121 may generate the latch signal LAT having a logic high level, responsive to the power-up signal PWR that is activated to have a logic high level in the power-up period. Meanwhile, the latch signal generation circuit 121 may generate the latch signal LAT having a logic low level, responsive to the feedback voltage FV having a voltage level with a logic low level, when at least one of the mats (not illustrated) to which the word lines (e.g., WL in FIG. 1) that are driven by being supplied with the operating power VPPC have been connected is selected by mat selection signals MAT_SELB<n> and MAT_SELB<n+1> and the voltage level of a second voltage V2 is set as a logic high level.

The first voltage setting circuit 123 may be electrically connected to the latch signal generation circuit 121, and may receive the latch signal LAT from the latch signal generation circuit 121. The first voltage setting circuit 123 may generate a first voltage V1 responsive to the latch signal LAT and the test mode signal TM. The test mode signal TM may be activated to a logic high level for the test mode for setting the operating power VPPC as the high voltage VPP. The first voltage setting circuit 123 may generate the first voltage V1 having a logic high level, when the level of the latch signal LAT is set as a logic high level or the test mode signal TM is activated to a logic high level. The first voltage setting circuit 123 may generate the first voltage V1 having a logic low level, when the level of the latch signal LAT is set as a logic low level or the test mode signal TM is deactivated to a logic low level.

The second voltage setting circuit 125 may generate the second voltage V2 responsive to the mat selection signals MAT_SELB<n> and MAT_SELB<n+1> and may generate the feedback voltage FV responsive to the second voltage V2. Each of the mat selection signals MAT_SELB<n> and MAT_SELB<n+1> may correspond to one of the mats (not illustrated) to which the word lines (e.g., WL) that are driven by being supplied with the operating power VPPC have been connected and may be activated when a corresponding mat is selected for the active operation or the refresh operation. The second voltage setting circuit 125 may generate the second voltage V2 having a logic high level, when one of the mat selection signals MAT SELB<n> and MAT_SELB<n+1> is activated to a logic low level. The second voltage setting circuit 125 may generate the feedback voltage FV having a logic low level by inverting and buffering the second voltage V2 having a logic high level. The second voltage setting circuit 125 may generate the second voltage V2 having a logic low level, when all the mat selection signals MAT_SELB<n> and MAT_SELB<n+1> are deactivated to a logic high level for the precharge operation after the active operation or the refresh operation is performed, and may generate the feedback voltage FV having a logic high level.

The control signal output circuit 127 may be electrically connected to the first voltage setting circuit 123 and the second voltage setting circuit 125, may receive the first voltage V1 from the first voltage setting circuit 123, and may receive the second voltage V2 from the second voltage setting circuit 125. The control signal output circuit 127 may generate the power control signal VEN responsive to the first voltage V1 and the second voltage V2. The control signal output circuit 127 may generate the power control signal VEN that is activated to a logic high level in order to set the operating power VPPC as the high voltage VPP, when the voltage level of one of the first voltage V1 and the second voltage V2 is set as a logic high level. The control signal output circuit 127 may generate the power control signal VEN that is activated to a logic high level by receiving the first voltage V1 having a logic high level in the power-up period or the test mode. The control signal output circuit 127 may generate the power control signal VEN that is deactivated to a logic low level, when the first voltage V1 and the second voltage V2 are set as a logic low level. The control signal output circuit 127 may generate the power control signal VEN that is deactivated to a logic low level by receiving the first voltage V1 and the second voltage V2 which have a logic low level, when the precharge operation is performed after the active operation or the refresh operation is performed on a selected mat responsive to the mat selection signals MAT_SELB<n> and MAT_SELB<n+1>.

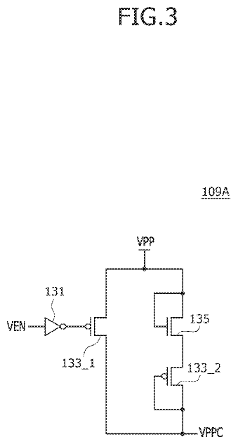

FIG. 3 is a circuit diagram of an operating power generation circuit 109A according to an example of the operating power generation circuit 109 of FIG. 1. As illustrated in FIG. 3, the operating power generation circuit 109A may include an inverter 131, PMOS transistors 133_1 and 133_2, and an NMOS transistor 135. The inverter 131 may output the power control signal VEN by inverting and buffering the power control signal VEN. The PMOS transistor 133_1 may operate as a switching element that is turned on responsive to the output signal of the inverter 131. The PMOS transistor 133_1 may set the operating power VPPC as the high voltage VPP when the power control signal VEN is activated to a logic high level. The NMOS transistor 135 and the PMOS transistor 133_2 may operate as diode elements and clamp the voltage level of the operating power VPPC. That is, when the PMOS transistor 133_1 is in a turn off state, the voltage level of the operating power VPPC may be “adjusted” or changed by the NMOS transistor 135 and the PMOS transistor 133_2 so that the voltage level of the operating power VPPC, which is output to a VPPC output voltage node of the same name (VPPC), does not drop to a voltage level more than the voltage drops across the NMOS transistor 135 and 133_2. That voltage is calculated by subtracting, from the high voltage VPP, the voltage level of the sum of the threshold voltage of the NMOS transistor 135 and the threshold voltage of the PMOS transistor 133_2.

FIG. 4 is a block diagram of a word line driver 111A according to an example of the word line driver 111 of FIG. 1. As illustrated in FIG. 4, the word line driver 111A may include a main word line driver group 141 and a sub-word line driver group 143.

The main word line driver group 141 may include a plurality of main word line drivers MWL DRV. Each of the main word line drivers MWL DRV may drive the main word line MWLB by the operating power VPPC responsive to the mat selection signal MAT_SEL, the row address RADD, and the word line off signal WLOFF. Each of the main word line drivers MWL DRV may drive, by the operating power VPPC, the main word line MWLB that is selected by the mat selection signal MAT_SEL and the row address RADD in the state in which the word line off signal WLOFF has been deactivated. The main word line driver group 141 may be electrically connected to the sub-word line driver group 143 through the main word line MWLB. The main word line MWLB corresponding to the mat selection signal MAT_SEL and the row address RADD may be variously set according to an embodiment.

The sub-word line driver group 143 may include a plurality of sub-word line drivers SWL DRV. Each of the sub-word line drivers SWL DRV may drive the word line WL responsive to a selection signal FX, an inverted selection signal FXB, and the main word line MWLB. Each of the sub-word line drivers SWL DRV may drive the word line WL that is selected responsive to the selection signal FX, the inverted selection signal FXB, and the main word line MWLB. The word line WL corresponding to the selection signal FX, the inverted selection signal FXB, and the main word line MWLB may be variously set according to an embodiment.

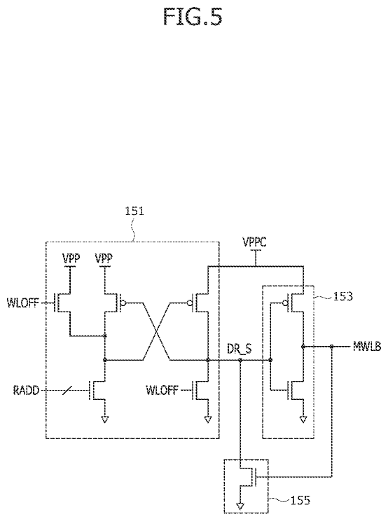

FIG. 5 is a circuit diagram according to an example of the main word line driver MWL DRV. The main word line driver MWL DRV may be selected among the main word line drivers MWL DRV of the main word line driver group 141 by the mat selection signal MAT_SEL in the active operation or the refresh operation.

As illustrated in FIG. 5, the main word line driver MWL DRV may include a driving signal generation circuit 151, a driving circuit 153, and a driving signal drive circuit 155. The driving signal generation circuit 151 may generate a driving signal DR_S that is driven by the operating power VPPC when the driving signal generation circuit 151 may receive the row address RADD having a logic high level in the state in which the word line off signal WLOFF has been deactivated to a logic low level. The driving circuit 153 may be electrically connected to the driving signal generation circuit 151, and may receive the driving signal DR_S from the driving signal generation circuit 151. The driving circuit 153 may activate the main word line MWLB by driving the main word line MWLB to a logic low level, when the driving signal DR_S that is driven by the operating power VPPC is received. The operating power VPPC may have a low voltage level due to a leakage current in the state in which the main word line MWLB has not been driven because an active operation or a refresh operation had not been performed. The driving signal drive circuit 155 may set the level of the driving signal DR_S as a logic low level in the state in which the main word line MWLB has been deactivated to a logic high level.

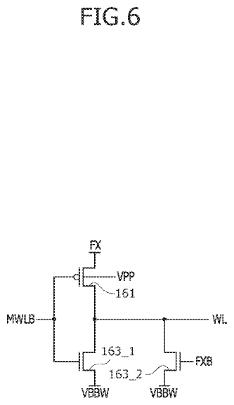

FIG. 6 is a circuit diagram according to an example of the sub-word line driver SWL DRV.

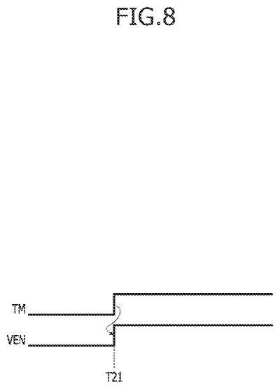

As illustrated in FIG. 6, the sub-word line driver SWL DRV may include a PMOS transistor 161 and NMOS transistors 163_1 and 163_2. The PMOS transistor 161 may be turned on when the main word line MWLB is in the state in which the main word line MWLB has been activated to a logic low level, and may drive the word line WL by the selection signal FX. The PMOS transistor 161 may be supplied with the high voltage VPP as a bulk voltage for setting a threshold voltage. The selection signal FX may be activated to the operating power VPPC in order to drive the word line WL, corresponding to the active operation or the refresh operation, to a logic high level. The NMOS transistor 163_1 may be turned on when the main word line MWLB is in the state in which the main word line MWLB has been driven by the operating power VPPC, and may drive the word line WL by a back bias voltage VBBW. The back bias voltage VBBW may be generated by a pumping circuit within the semiconductor device 10 so that the back bias voltage VBBW having a lower level than a ground voltage VSS that is applied by the controller (e.g., 31 in FIG. 8) is generated. The NMOS transistor 163_2 may be turned on in response to the inverted selection signal FXB, and may drive the word line WL by the back bias voltage VBBW. The inverted selection signal FXB may be activated to the operating power VPPC in order to drive the word line WL to the back bias voltage VBBW when an active operation or a refresh operation is not performed.

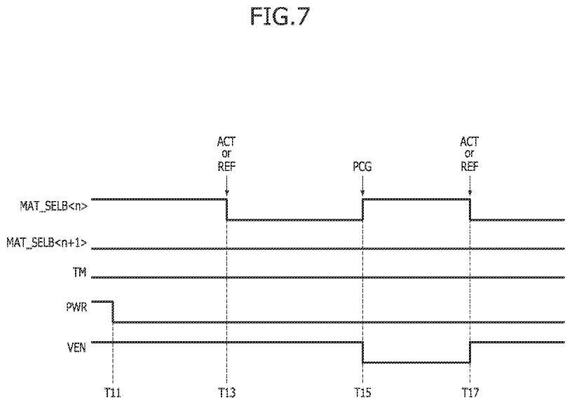

FIGS. 7 and 8 are timing diagrams for describing an operation of the power control signal generation circuit 107 for controlling the generation of the operating power VPPC in the semiconductor device 10. An operation of the power control signal generation circuit 107 is described as follows by dividing the operation into a first case in which a precharge operation is performed after an active operation or a refresh operation is performed and a second case in which a test mode operation is performed in the semiconductor device 10 with reference to FIGS. 2, 7, and 8.

Hereinafter, an operation of the power control signal generation circuit 107 when a precharge operation is performed after an active operation or a refresh operation is performed in the semiconductor device 10 is described with reference to FIGS. 2 and 7. First, the power control signal generation circuit 107 may set the operating power VPPC as the high voltage VPP by generating the power control signal VEN that is activated to a logic high level because the power-up signal PWR having a logic high level is received during a power-up period in which the power source voltage VDD rises from 0 V to a target voltage level, that is, during a period prior to T11. The voltage level of the operating power VPPC can be prevented from being excessively lowered because the operating power VPPC is set as the high voltage VPP responsive to the power-up signal PWR before the active operation or the refresh operation is performed. Next, the a power control signal generation circuit (VEN GEN) 107 may maintain the state in which the operating power VPPC has been set as the high voltage VPP by generating the power control signal VEN that is activated to a logic high level during a period from T13 to T15 in which the active operation or the refresh operation is performed on a mat that is selected by the mat selection signal MAT_SELB<n> having a logic low level. Next, the power control signal generation circuit (VEN GEN) 107 may maintain the voltage level of the operating power VPPC so that the voltage level of the operating power VPPC does not drop to a voltage level or less, which is calculated by subtracting a preset voltage level from the voltage level of the high voltage VPP, by generating the power control signal VEN that is deactivated to a logic low level during a period from T15 to T17 in which the level of the mat selection signal MAT_SELB<n> is set as a logic high level in order to perform the precharge operation on the mat on which the active operation or the refresh operation has been performed.

Hereinafter, an operation of the power control signal generation circuit 107 when a test mode operation is performed in the semiconductor device 10 is described with reference to FIGS. 2 and 8. The power control signal generation circuit 107 may set the operating power VPPC as the high voltage VPP by generating the power control signal VEN that is activated to a logic high level during a period after T21 at which the test mode signal TM is activated to a logic high level for the test mode operation. The voltage level of the operating power VPPC can be prevented from being excessively lowered because the operating power VPPC is set as the high voltage VPP in the test mode operation.

FIG. 9 is a block diagram illustrating a semiconductor system 3 according to an embodiment of the present disclosure. As illustrated in FIG. 9, the semiconductor system 3 may include the controller 31 and a semiconductor device 33.

The controller 31 may include a first control pin 31_1 and a second control pin 31_3. The semiconductor device 33 may include a first device pin 33_1 and a second device pin 33_3. The controller 31 may transmit the command address CA to the semiconductor device 33 through a first transmission line 32_1 that is connected between the first control pin 31_1 and the first device pin 33_1. Each of the first control pin 31_1, the first transmission line 32_1, and the first device pin 33_1 may be implemented in a plural number depending on the number of bits of the command address CA. The controller 31 may apply the power source voltage VDD to the semiconductor device 33 through a second transmission line 32_3 that is connected between the second control pin 31_3 and the second device pin 33_3.

The semiconductor device 33 may drive the operating power VPPC that is used to drive the word line WL by receiving the command address CA and the power source voltage VDD from the controller 31. The semiconductor device 33 may set the operating power VPPC as the high voltage VPP by generating the power control signal VEN that is activated during the power-up period in which the power source voltage VDD rises from 0 V to a target voltage level or during an interval in which a test mode operation is performed. The power-up period may thus be considered as substantially equal to the time between when VDD reaches a target voltage level and the end or completion of a test mode operation.

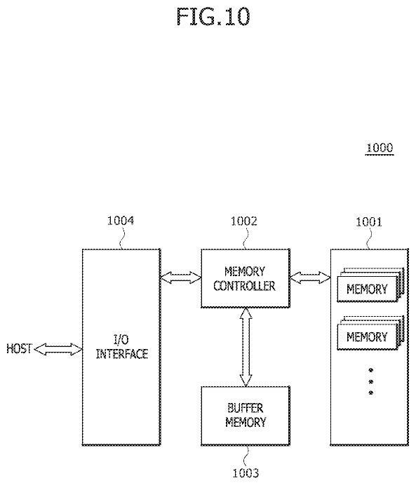

The semiconductor device 10 described above with reference to FIG. 1 may be applied to an electronic system which includes a memory system, a graphic system, a computing system, and a mobile system. For example, referring to FIG. 10, an electronic system 1000 according to an embodiment of the present disclosure may include a data storage unit 1001, a memory controller 1002, buffer memory 1003, and an input and output (I/O) interface 1004.

The data storage unit 1001 may store data (not illustrated) that is applied by the memory controller 1002, read the stored data (not illustrated), and output the read data to the memory controller 1002, in response to a control signal from the memory controller 1002. The data storage unit 1001 may include nonvolatile memory capable of continuously storing data without losing the data although power is blocked. The nonvolatile memory may be implemented as flash memory (e.g., NOR flash memory or NAND flash memory), phase change random access memory (PRAM), resistive random access memory (RRAM), spin transfer torque random access memory (STTRAM), or magnetic random access memory (MRAM).

The memory controller 1002 may decode an instruction that is applied by an external device (or a host device) through the I/O interface 1004, and may control the input and output of data to and from the data storage unit 1001 and the buffer memory 1003 responsive to the results of the decoding. In FIG. 10, the memory controller 1002 has been indicated as one block, but the memory controller 1002 may include a controller for controlling the data storage unit 1001 and a controller for controlling the buffer memory 1003 that is volatile memory, which are independently constructed.

The buffer memory 1003 may temporarily store data to be processed by the memory controller 1002, that is, data (not illustrated) that are input to and output from the data storage unit 1001. The buffer memory 1003 may store data (not illustrated) that are applied by the memory controller 1002 in response to a control signal from the memory controller 1002. The buffer memory 1003 may include the semiconductor device 10 described with reference to FIG. 1. The buffer memory 1003 may read data that have been stored in the buffer memory 1003, and may output the read data to the memory controller 1002. The buffer memory 1003 may include volatile memory, such as dynamic random access memory (DRAM), mobile DRAM, and static random access memory (SRAM).

The I/O interface 1004 may provide a physical connection between the memory controller 1002 and an external device (or a host) so that the memory controller 1002 may receive a control signal for the input and output of data to and from the external device and may exchange data with the external device. The I/O interface 1004 may include one of various interface protocols, such as a USB, an MMC, PCI-E, an SAS, SATA, PATA, an SCSI, an ESDI, and IDE.

The electronic system 1000 may be used as an auxiliary memory device of a host device or an external storage device. The electronic system 1000 may include a solid state disk (SSD), universal serial bus (USB) memory, a secure digital (SD) card, a mini secure digital (mSD) card, a micro SD card, a secure digital high capacity (SDHC) card, a memory stick card, a smart media (SM) card, a multi-media card (MMC), an embedded MMC (eMMC), and a compact flash (CF) card.

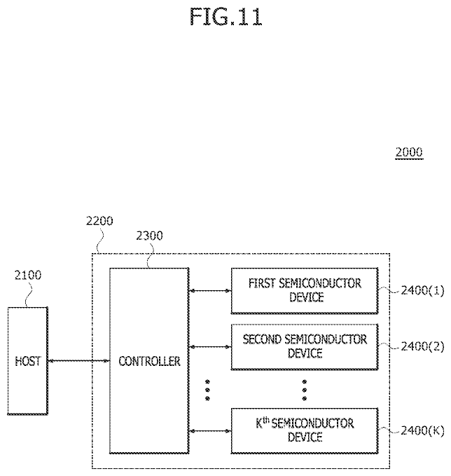

FIG. 11 is a block diagram illustrating a construction according to an embodiment of an electronic system 2000 according to another embodiment of the present disclosure. As illustrated in FIG. 11, the electronic system 2000 may include a host 2100 and a semiconductor system 2200.

The host 2100 and the semiconductor system 2200 may mutually transmit signals by using an interface protocol. The interface protocol that is used between the host 2100 and the semiconductor system 2200 may include a multi-media card (MMC), an enhanced small disk interface (ESDI), integrated drive electronics (IDE), peripheral component interconnect-express (PCI-E), advanced technology attachment (ATA), serial ATA (SATA), parallel ATA (PATA), a serial attached SCSI (SAS), and a universal serial bus (USB).

The semiconductor system 2200 may include a controller 2300 and semiconductor devices 2400(1:K). The semiconductor devices 2400(1:K) may each include the semiconductor device 10 described with reference to FIG. 1. The semiconductor devices 2400(1:K) may each be implemented as one of dynamic random access memory (DRAM), phase change random access memory (PRAM), resistive random access memory (RRAM), magnetic random access memory (MRAM), and ferroelectric random access memory (FRAM).

The embodiments of the present disclosure have been described so far. A person having ordinary knowledge in the art to which the present invention pertains will understand that the present invention may be implemented in a modified form without departing from an intrinsic characteristic of the present disclosure. Accordingly, the disclosed embodiments should be considered from a descriptive viewpoint, not from a limitative viewpoint. The range of the present disclosure is described in the claims not the aforementioned description, and all differences within an equivalent range thereof should be construed as being included in the present disclosure.

What is claimed is:

1. A semiconductor device comprising:
a power control signal generation circuit configured to generate a power control signal that is activated when at least one of a power-up period is started and a test mode operation is performed; and
an operating power generation circuit configured to set operating power supplied to a word line driver as a high voltage responsive to the power control signal.

2. The semiconductor device of claim 1, wherein the power control signal generation circuit is configured to generate the power control signal by receiving a power-up signal during a power-up period.

3. The semiconductor device of claim 1, wherein the power control signal generation circuit is configured to generate the power control signal, by receiving a test mode signal when the test mode operation is performed.

4. The semiconductor device of claim 1, wherein the power control signal generation circuit comprises:
a latch signal generation circuit configured to generate a latch signal responsive to a power-up signal and a feedback voltage;
a first voltage setting circuit configured to generate a first voltage responsive to the latch signal and a test mode signal;
a second voltage setting circuit configured to generate a second voltage responsive to a mat selection signal and configured to generate the feedback voltage responsive to the second voltage; and
a control signal output circuit configured to generate the power control signal responsive to the first voltage and the second voltage.

5. The semiconductor device of claim 4, wherein the latch signal generation circuit is configured to generate the latch signal having a first logic level responsive to the power-up signal during the power-up period.

6. The semiconductor device of claim 5, wherein the first voltage setting circuit is configured to generate the first voltage having the first logic level when the latch signal has the first logic level.

7. The semiconductor device of claim 5, wherein the control signal output circuit is configured to generate the power control signal that is activated responsive to the first voltage when the latch signal has the first logic level.

8. The semiconductor device of claim 4, wherein the first voltage setting circuit is configured to generate the first voltage having a first logic level responsive to the test mode signal in the test mode operation.

9. The semiconductor device of claim 8, wherein the control signal output circuit is configured to generate the power control signal that is activated when the first voltage has the first logic level.

10. The semiconductor device of claim 1, wherein the operating power generation circuit comprises a switching element that is connected between an output voltage node and the high voltage and which is configured to be turned on and off responsive to the power control signal.

11. The semiconductor device of claim 10, wherein the operating power generation circuit additionally comprises at least one diode element that is connected in parallel to the switching between an output voltage node and the high voltage.

12. The semiconductor device of claim 1, wherein the operating power generation circuit is configured to maintain a voltage level of the operating power so that the voltage level of the operating power does not drop below a predetermined a voltage level when the power control signal is deactivated.

13. A semiconductor device comprising:
a latch signal generation circuit configured to generate a latch signal responsive to a power-up signal and a feedback voltage;
a first voltage setting circuit configured to generate a first voltage responsive to the latch signal and a test mode signal;
a second voltage setting circuit configured to generate a second voltage responsive to a mat selection signal and configured to generate the feedback voltage responsive to the second voltage; and
a control signal output circuit configured to generate a power control signal for setting a voltage level of operating power that is supplied to a word line driver responsive to the first voltage and the second voltage.

14. The semiconductor device of claim 13, wherein the latch signal generation circuit is configured to generate the latch signal having a first logic level, the latch signal being generated responsive to the power-up signal during the power-up period.

15. The semiconductor device of claim 14, wherein the first voltage setting circuit is configured to generate the first voltage having the first logic level when the latch signal is set as the first logic level.

16. The semiconductor device of claim 14, wherein the control signal output circuit is configured to generate the power control signal responsive to the first voltage when the latch signal is the first logic level.

17. The semiconductor device of claim 13, wherein the first voltage setting circuit is configured to generate the first voltage having the first logic level responsive to the test mode signal in a test mode operation.

18. The semiconductor device of claim 17, wherein the control signal output circuit is configured to generate the power control signal that is activated when the first voltage is set as the first logic level.

19. The semiconductor device of claim 13, further comprising an operating power generation circuit configured to set the operating power as a high voltage in response to the power control signal.

20. The semiconductor device of claim 19, wherein the operating power generation circuit comprises:
a switching element that is connected between an output voltage node and the high voltage and that is turned on and off responsive to the power control signal; and
at least one diode element that is connected in parallel to the switching element and between the output voltage node and the high voltage.
